(19) United States
(12) Patent Application Publication
(10) Pub. No.: US 2025/0199094 A1
(43) Pub. Date: Jun. 19, 2025

(54) MAGNETIC SENSOR AND STATE DETECTION DEVICE

(71) Applicant: SUZHOU NOVOSENSE MICROELECTRONICS CO., LTD., Suzhou, Jiangsu (CN)

(72) Inventor: Fute YUAN, Suzhou (CN)

(73) Assignee: SUZHOU NOVOSENSE MICROELECTRONICS CO., LTD., Suzhou, Jiangsu (CN)

(21) Appl. No.: 18/949,841

(22) Filed: Nov. 15, 2024

(30) Foreign Application Priority Data
Dec. 15, 2023 (CN) 202311726881.0

(51) Int. Cl. G01R 33/07; G01D 5/14; G01R 33/00

(52) U.S. Cl. CPC G01R 33/07; G01D 5/145; G01R 33/0011

(57) ABSTRACT

The present application discloses a magnetic sensor and state detection device, the magnetic sensor, comprising: a substrate, including a carrying surface; a first sensing assembly, a second sensing assembly, a third sensing assembly and a fourth sensing assembly provided at a first position, a second position, a third position and a fourth position respectively; each of the first sensing assembly and the third sensing assembly comprises two sensing elements spaced apart along a first direction, and each of the second sensing assembly and the fourth sensing assembly comprises two sensing elements spaced apart along a second direction; and the first direction and the second direction form a first angle. The magnetic sensor and state detection device provided by the present application can reduce the demand for the number of sensing elements, achieve lower costs and energy consumption, and save circuit area, while balance interference resistance and high precision.

### TECHNICAL FIELD

The present application belongs to the field of testing and measurement technology, and in particular, relates to a magnetic sensor and a state detection device.

### BACKGROUND

The technology for detecting a current state of objects, especially for detecting data related to the motion state or position state of the objects, plays an important role in industrial, automotive, and commercial fields. Specifically, it can realize various system monitoring and alarming, such as idling and sliding, various automatic motion feedback controls, such as motion or posture control, or triggering of various operations. In existing technology, magnetic sensors are configured to sense based on the distribution pattern of magnetic lines, but regardless of whether the sensing direction of the sensor is vertical or horizontal, it will be interfered with by the other sensing direction, resulting in low credibility of the detection results.

Existing technology also uses multiple sensing parts for comprehensive sensing, but due to the limitations of the overall layout and internal structure of the sensing parts, it leads to a large number of required components, high cost, large circuit area and complex circuit structure, high energy consumption, and cannot be applied to scenarios with small volume and low power consumption requirements.

### SUMMARY

One of the objectives of the present application is to provide a magnetic sensor to solve a technical problem of poor anti-interference ability and large circuit area and complex structure of magnetic sensors in prior art.

Another objective of the present application is to provide a state detection device.

To achieve the above objectives, an embodiment of the present application provides a magnetic sensor, comprising: a substrate, including a carrying surface; a first sensing assembly, provided at a first position on the carrying surface, comprising a first sensing element and a second sensing element spaced apart along a first direction; a second sensing assembly, provided at a second position on the carrying surface, comprising a third sensing element and a fourth sensing element spaced apart along a second direction; a third sensing assembly, provided at a third position on the carrying surface, comprising a fifth sensing element and a sixth sensing element spaced apart along the first direction; a fourth sensing assembly, provided at a fourth position on the carrying surface, comprising a seventh sensing element and an eighth sensing element spaced apart along the second direction; wherein a convex polygon formed by connecting the first position, the second position, the third position and the fourth position is center-symmetrical with respect to a geometric center of the carrying surface; the first direction and the second direction form a first angle.

To achieve the above objectives, an embodiment of the present application provides a state detection device, comprising the magnetic sensor according to any one of the magnetic sensor mentioned in the present application; and, a first intermediate signal operation module coupled to the first sensing element and the second sensing element, a second intermediate signal operation module coupled to the fifth sensing element and the sixth sensing element, a third intermediate signal operation module coupled to the third sensing element and the fourth sensing element, a fourth intermediate signal operation module coupled to the seventh sensing element and the eighth sensing element; and, a first output signal operation module coupled to the first intermediate signal operation module and the second intermediate signal operation module, a second output signal operation module coupled to the third intermediate signal operation module and the fourth intermediate signal operation module; and, an output processing module coupled to the first output signal operation module and the second output signal operation module; and, a storage module coupled to the output processing module; or, a first intermediate signal operation module coupled to the first sensing element and the fourth sensing element, a second intermediate signal operation module coupled to the seventh sensing element and the sixth sensing element, a third intermediate signal operation module coupled to the second sensing element and the eighth sensing element, a fourth intermediate signal operation module coupled to the third sensing element and the fifth sensing element; and, a first output signal operation module coupled to the first intermediate signal operation module and the second intermediate signal operation module, a second output signal operation module coupled to the third intermediate signal operation module and the fourth intermediate signal operation module; and, an output processing module coupled to the first output signal operation module and the second output signal operation module; and, a storage module coupled to the output processing module; wherein the first output signal operation module and the second output signal operation module are used to perform a second operation, the output processing module is used to calculate and generate rotation angle data, and the storage module is used to store at least correction information for the rotation angle data.

Compared with the prior art, a magnetic sensor provided by the present application, by setting sensing assemblies at four positions with center-symmetry on the substrate, and configuring the sensing assemblies so that two of them have sensing elements arranged along a first direction and the other two along a second direction, can obtain sensitivity in at least two directions, and signals obtained by the two sensing assemblies can complement each other to obtain magnetic field information in the entire area. Based on the layout and internal structure configuration of the sensing assemblies, it can greatly reduce the demand for the number of sensing elements, achieve lower costs and energy consumption, and save circuit area. Even if magnetic field interference occurs in a direction, the two sensing assemblies present changes in a same direction externally and can resist such interference so that it is not reflected in the output of the magnetic sensor, thereby improving the credibility and accuracy of the outputs.

### BRIEF DESCRIPTION OF THE DRAWINGS

FIG. 1 shows a structural schematic diagram of a magnetic sensor in an embodiment of the present application.

FIG. 2 shows a structural schematic diagram of a sensing assembly in an embodiment of the present application.

FIG. 3 shows a sectional view of a sensing assembly along a first section line R1 in FIG. 2 in an embodiment of the present application.

FIG. 4 shows a structural schematic diagram of a first example of a sensing element in an embodiment of the present application.

FIG. 5 shows a structural schematic diagram of a second example of a sensing element in an embodiment of the present application.

FIG. 6 shows a structural schematic diagram of a third example of a sensing element in an embodiment of the present application.

FIG. 7 shows a structural schematic diagram of a magnetic sensor in a first embodiment of the present application.

FIG. 8 shows a sectional view of a magnetic sensor along a second section line R2 in FIG. 7 in the first embodiment of the present application.

FIG. 9 shows a magnetic line distribution diagram of a sensing assembly along a third section line R3 in FIG. 7 under a magnetic field in a Z direction in the first embodiment of the present application.

FIG. 10 shows a magnetic line distribution diagram of a sensing assembly along the third section line R3 in FIG. 7 under a magnetic field in an X direction in the first embodiment of the present application.

FIG. 11 shows a structural schematic diagram of a state detection device in the first embodiment of the present application.

FIG. 12 shows a waveform diagram of an output magnetic signal of a magnetic sensor without interference in the first embodiment of the present application.

FIG. 13 shows a waveform diagram of an output magnetic signal of a magnetic sensor with interference in the first embodiment of the present application.

FIG. 14 shows a structural schematic diagram of a magnetic sensor in a second embodiment of the present application.

FIG. 15 shows a structural schematic diagram of a state detection device in the second embodiment of the present application.

FIG. 16 shows a structural schematic diagram of a magnetic sensor in another embodiment of the present application.

FIG. 17 shows a structural schematic diagram of a state detection device in a third embodiment of the present application.

FIG. 18 shows structural schematic diagram of a state detection device in a fourth embodiment of the present application.

### DETAILED DESCRIPTION

The present application will be described in detail below with reference to the specific embodiments shown in the drawings. However, these embodiments do not limit the present application. Structural, methodological, or functional modifications made by those skilled in the art based on these embodiments are included in the scope of protection of the present application.

It should be noted that the term “include” or any of its other variants is intended to cover non-exclusive inclusion, so that a process, method, article, or device that includes a series of elements not only includes those elements, but also includes other elements not explicitly listed, or includes elements inherent to such process, method, article, or device. In addition, the terms “first”, “second”, “third”, “fourth”, “fifth”, “sixth”, “seventh”, “eighth”, etc. are used only for descriptive purposes and cannot be understood as indicating or implying relative importance.

Sensors used for detecting state data such as angle, stroke, speed, and direction can be widely applied in various scenarios, for example, measuring the rotation amount of gears in mechanical devices, and measuring the stroke size of valve switches. Based on this, it can realize idling and sliding detection for devices containing wheel-like components such as automobiles, and can also realize motion feedback detection for automated production lines.

To adapt to various difficult working conditions, it is necessary to use a non-contact measurement method with anti-vibration and anti-oil pollution performance, high accuracy, and fast response speed for state data measurement. Therefore, using a magnetic sensor for detection is a preferable choice. Magnetic sensors can usually be divided into components made based on the Hall effect principle and components made based on the magnetoresistive effect principle. The components made based on the Hall effect principle bas advantages of strong compatibility with

CMOS (Complementary Metal Oxide Semiconductor) process, small size, and high cost-performance ratio, while the components made based on the magnetoresistive effect principle has higher sensitivity, lower IC (Integrated Circuit) power consumption, and higher detection accuracy. Any of the above-mentioned magnetic sensors or other sensors not mentioned that can be used to sense physical data can be applied to replace any embodiment provided below in the present application with their own advantages as beneficial effects.

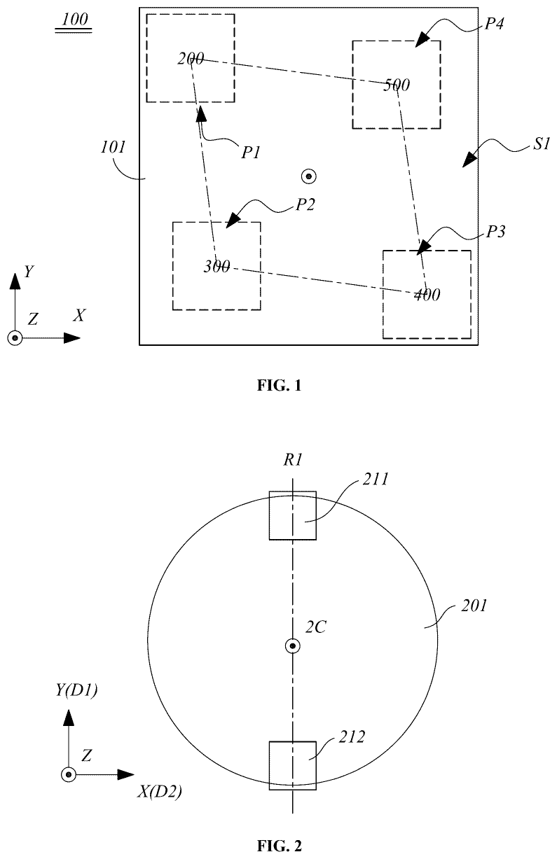

As shown in FIG. 1, an embodiment of the present application provides a magnetic sensor 100.

The magnetic sensor 100 comprises a sensing assembly and a substrate 101. The definition of the sensing assembly does not mean that components inside it are integrally packaged necessarily. In embodiments without integral packaging, descriptions of the sensing assembly below can be interpreted as referring to an area in the magnetic sensor 100 used for setting up the components contained in the sensing assembly, that is, interpreting the sensing assembly as an area in the magnetic sensor 100 used for realizing sensing.

The substrate 101 includes a carrying surface S1. The carrying surface S1 can be any extension surface of the substrate 101, and can be configured as rectangular, circular or other shapes. The sensing assembly included in the magnetic sensor can be provided on the carrying surface S1. In addition, the carrying surface S1 can be interpreted as a surface used for carrying components; a single substrate 101 can have one carrying surface or multiple carrying surfaces.

The carrying surface S1 includes a first position P1, a second position P2, a third position P3 and a fourth position P4; different positions on the carrying surface S1 can refer to a specific area, the area of which is smaller than a total area of the carrying surface S1. A position on the carrying surface S1 can also refer to a specific positioning point and a surrounding area of the specific positioning point.

A convex polygon can be formed by connecting the first position P1, the second position P2, the third position P3 and the fourth position P4; specifically, this convex polygon can be formed by sequentially connecting the first position P1, the second position P2, the third position P3 and the fourth position P4. When the first position P1, the second position P2, the third position P3 and the fourth position P4 represent areas on the carrying surface S1, the convex polygon can be formed by connecting geometric centers of the four areas.

In an embodiment, the convex polygon formed by connecting the first position P1, the second position P2, the third position P3 and the fourth position P4 is center-symmetrical with respect to a geometric center of the carrying surface S1. In an embodiment, the convex polygon can be a parallelogram, specifically the convex polygon can be a rectangle or a square.

The magnetic sensor comprises a first sensing assembly 200, a second sensing assembly 300, a third sensing assembly 400 and a fourth sensing assembly 500. The first sensing assembly 200 is provided at a first position P1 on the carrying surface S1; the second sensing assembly 300 is provided at a second position P2 on the carrying surface S1; the third sensing assembly 300 is provided at a third position P3 on the carrying surface S1; the fourth sensing assembly 400 is provided at a fourth position P4 on the carrying surface S1.

When the convex polygon formed by connecting the first position P1, the second position P2, the third position P3 and the fourth position P4 is configured as a center-symmetrical figure, the magnetic sensor can have a wider sensing area, and the sensing signal has certain periodicity, which is convenient for subsequent calculation and processing. In an embodiment, the first position P1, the second position P2, the third position P3 and the fourth position P4 are distributed at edge positions of the carrying surface S1; the first position P1, the second position P2, the third position P3 and the fourth position P4 are relatively far from a geometric center of the carrying surface S1 compared to other positions on the carrying surface.

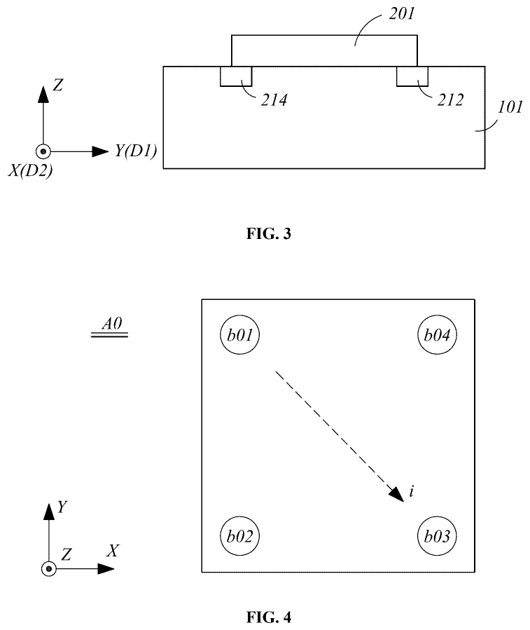

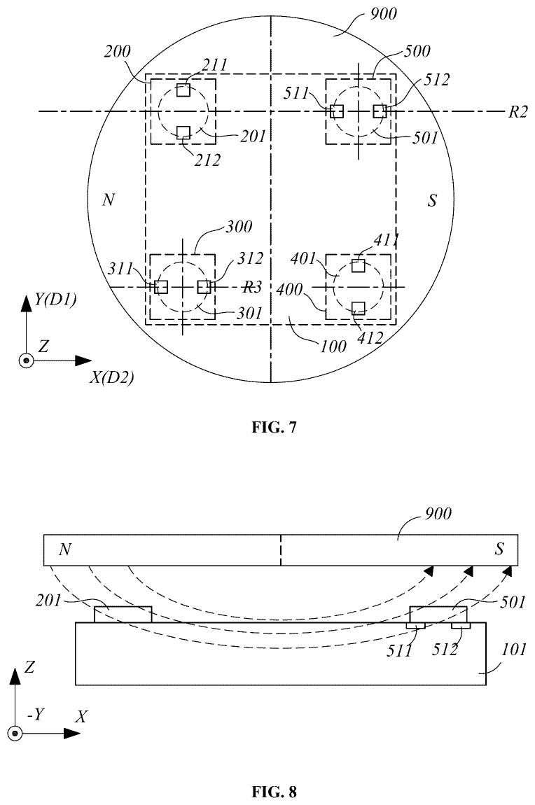

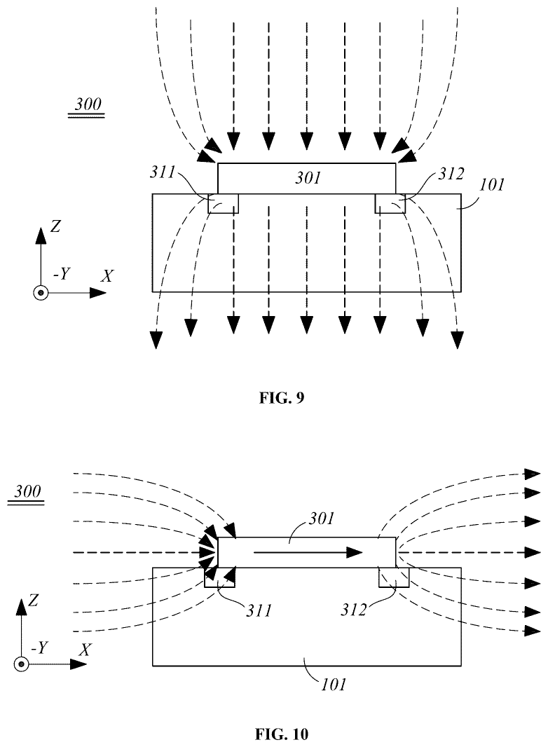

As shown in FIG. 2, FIG. 3, FIG. 7, FIG. 8, FIG. 9. FIG. 10, FIG. 14, and FIG. 16, the first sensing assembly 200 comprises a first sensing element 211 and a second sensing element 212 spaced apart along a first direction D1.

The second sensing assembly 300 comprises a third sensing element 311 and a fourth sensing element 312 spaced apart along a second direction D2.

The third sensing assembly 400 comprises a fifth sensing element 411 and a sixth sensing element 412 spaced apart along the first direction D1.

The fourth sensing assembly 500 comprises a seventh sensing element 511 and an eighth sensing element 512 spaced apart along the second direction D2.

As such, sensing elements are arranged at intervals within the sensing assembly, allowing detection of magnetic field distribution and changes at more positions within the overall volume limitation of the magnetic sensor.

The first direction D1 and the second direction D2 form a first angle. As such, spacing directions of the sensing elements in the sensing assemblies are different from each other in pairs, regardless of positional relationships between the magnetic sensor and a magnetic device to be measured (for example, the magnetic device to be measured is set in a height direction or width direction of the magnetic sensor), the magnetic sensor can detect the magnetic field distribution and changes to dynamically grasp a motion state of the magnetic device to be measured; and because the spacing directions of the sensing elements in the sensing assemblies are the same in pairs, consistency in detecting magnetic field changes can also be maintained and the resistance to interfering magnetic fields can be enhanced.

In an embodiment, the number of sensing elements in the first sensing assembly 200 is 2; the first sensing assembly 200 only comprises the first sensing element 211 and the second sensing element 212.

In an embodiment, the number of sensing elements in the second sensing assembly 300 is 2; the second sensing assembly 300 only comprises the third sensing element 311 and the fourth sensing element 312.

In an embodiment, the number of sensing elements in the third sensing assembly 400 is 2; the third sensing assembly 400 only comprises the fifth sensing element 411 and the sixth sensing element 412.

In an embodiment, the number of sensing elements in the fourth sensing assembly 500 is 2; the fourth sensing assembly 500 only comprises the seventh sensing element 511 and the eighth sensing element 512.

Based on a layout method of sensing assemblies and sensing elements provided above, the number of sensing elements in any sensing assembly can be configured as only 2, which can maintain the anti-interference ability and magnetic field change detection ability of the magnetic sensor while reducing the requirement for the number of sensing elements, thereby reducing the volume and power consumption of the magnetic sensor, making it adaptable to highly integrated application scenarios. In a preferred embodiment, the number of sensing elements in the first sensing assembly 200, the second sensing assembly 300, the third sensing assembly 400 and the fourth sensing assembly 500 are all configured as 2, which can minimize the number of sensing elements to a greatest extent.

In an embodiment, the first angle is 90 degrees. A spacing direction of the sensing elements in the first sensing assembly 200 and the third sensing assembly 400 is perpendicular to a spacing direction of the sensing elements in the second sensing assembly 300 and the fourth sensing assembly 500, so that four sets of outputs formed by the sensing assemblies have a more orderly corresponding relationship.

In an embodiment, the convex polygon is a square. In this way, regardless of the position of the magnetic device to be measured relative to the magnetic sensor, when the magnetic device acts causing changes in the magnetic field, four sensing assemblies mentioned above can form regular and periodic outputs, facilitating subsequent processing of the outputs to obtain information reflecting the state of the magnetic device to be measured.

As shown in FIG. 7 and FIG. 14, in an embodiment, when the convex polygon is configured as a square, an extension direction of sides of the convex polygon can be parallel to the first direction D1 or the second direction D2. When the convex polygon is configured as other general rectangles or other regular polygons with an even number of sides, the extension direction of the sides of the general rectangle or regular polygon can also be parallel to the first direction D1 or the second direction D2.

As shown in FIG. 16, in an embodiment, when the convex polygon is configured as a square, an extension direction of sides of the convex polygon can form a 45-degree angle with the first direction D1 or the second direction D2. When the convex polygon is configured as other general rectangles or other regular polygons with an even number of sides, an angle bisector direction of interior angles of the general rectangle or regular polygon can be parallel to the first direction D1 or the second direction D2.

An embodiment of an internal structure of each sensing assembly will be described as follows, taking the first sensing assembly 200 as an example. Other sensing assemblies can be configured to have a same or similar structure as the first sensing assembly 200, especially when ignoring overall rotations or translations of the sensing assemblies, all sensing assemblies in the magnetic sensor can be configured to have a same construction, facilitating mass production.

As shown in FIG. 2 and FIG. 3, taking the embodiment shown in FIG. 7, FIG. 8, FIG. 9 and FIG. 10 or the embodiment shown in FIG. 14 as an example, the first sensing assembly 200 comprises a first magnetic flux concentrator 201.

Magnetic flux concentrators such as the first magnetic flux concentrator 201 can be made of ferromagnetic materials, preferably permalloy, nickel-iron high permeability alloy or metallic glass. In a preferred embodiment, the ferromagnetic material is metallic glass with a relatively low coercive field, which can avoid hysteresis effects. The degree of magnetization of the magnetic flux concentrator can be configured to be approximately isotropic.

The magnetic flux concentrator has a uniform thickness in a height direction of the magnetic flux concentrator, or the thickness of the central part of the magnetic flux concentrator is greater than the thickness of the edges of the magnetic flux concentrator. The magnetic flux concentrator can be configured to have any shape with geometric symmetry.

The first sensing element 211 and the second sensing element 212 are provided on an extension surface of the first magnetic flux concentrator 201. The first sensing element 211 and the second sensing element 212 are provided close to an extension surface of the first magnetic flux concentrator 201. In an embodiment, the magnetic field of the magnetic device to be measured near the extension surface is deflected along a direction towards the extension surface due to the magnetic flux concentration effect of the first magnetic flux concentrator 201.

The first direction D1 and the second direction D2 are parallel to the extension surface of the first magnetic flux concentrator 201. The spacing direction of the above-mentioned sensing elements is parallel to the extension surface of the magnetic flux concentrator. As such, the magnetic field of the magnetic device to be measured near the extension surface is deflected along a direction towards the extension surface, equivalent to deflecting towards a plane which is parallel to the first direction D1 and the second direction D2.

In an embodiment, a sensing direction of the first sensing element 211 is perpendicular to the extension surface of the first magnetic flux concentrator 201; in an embodiment, a sensing direction of the second sensing element 212 is perpendicular to the extension surface of the first magnetic flux concentrator 201; in an embodiment, both of the above two embodiments are configured simultaneously. As such, by using sensing elements with vertical sensing directions, the sensing elements themselves have higher sensing accuracy, thereby improving the overall sensing accuracy of the magnetic sensor.

Similarly, the third sensing element 311, the fourth sensing element 312, the fifth sensing element 411, the sixth sensing element 412, the seventh sensing element 511, and the eighth sensing element 512 can all be configured to have vertical sensing directions (or, be configured to have sensing directions perpendicular to the extension surface of the corresponding magnetic flux concentrator).

As shown in FIG. 7, FIG. 8, FIG. 9, FIG. 10, FIG. 14 and FIG. 16, for example, the second sensing assembly 300 comprises a second magnetic flux concentrator 301; the third sensing element 311 and the fourth sensing element 312 are provided on an extension surface of the second magnetic flux concentrator 301; the first direction D1 and the second direction D2 are parallel to the extension surface of the second magnetic flux concentrator 301; sensing directions of the third sensing element 311 and the fourth sensing element 312 are perpendicular to the extension surface of the second magnetic flux concentrator 301.

For example, the third sensing assembly 400 comprises a third magnetic flux concentrator 401; the fifth sensing element 411 and the sixth sensing element 412 are provided on an extension surface of the third magnetic flux concentrator 401; the first direction D1 and the second direction D2 are parallel to the extension surface of the third magnetic flux concentrator 401; sensing directions of the fifth sensing element 411 and the sixth sensing element 412 are perpendicular to the extension surface of the third magnetic flux concentrator 401.

For example, the fourth sensing assembly 500 comprises a fourth magnetic flux concentrator 501; the seventh sensing element 511 and the eighth sensing element 512 are provided on an extension surface of the fourth magnetic flux concentrator 501; the first direction D1 and the second direction D2 are parallel to the extension surface of the fourth magnetic flux concentrator 501; sensing directions of the seventh sensing element 511 and the eighth sensing element 512 are perpendicular to the extension surface of the fourth magnetic flux concentrator 501.

In other embodiments, a single sensing assembly may also comprise sensing elements with sensing directions in other directions.

In an embodiment, the first sensing element 211 and the second sensing element 212 are provided between the first magnetic flux concentrator 201 and the substrate 101. As such, the magnetic field direction can be more fully adjusted by the magnetic flux concentrator, and magnetic field components that conform to its sensing direction are always generated at the sensing element.

Similarly, the third sensing element 311, the fourth sensing element 312, the fifth sensing element 411, the sixth sensing element 412, the seventh sensing element 511, and the eighth sensing element 512 can all have similar position settings.

For example, the third sensing element 311 and the fourth sensing element 312 are provided between the second magnetic flux concentrator 301 and the substrate 101.

For example, the fifth sensing element 411 and the sixth sensing element 412 are provided between the third magnetic flux concentrator 401 and the substrate 101.

For example, the seventh sensing element 511 and the eighth sensing element 512 are provided between the fourth magnetic flux concentrator 501 and the substrate 101.

In an embodiment, the sensing elements do not directly contact the corresponding magnetic flux concentrators.

In an embodiment, any of the above sensing elements can include at least one Hall unit. In other words, any of the above sensing elements can detect magnetic fields following the Hall effect.

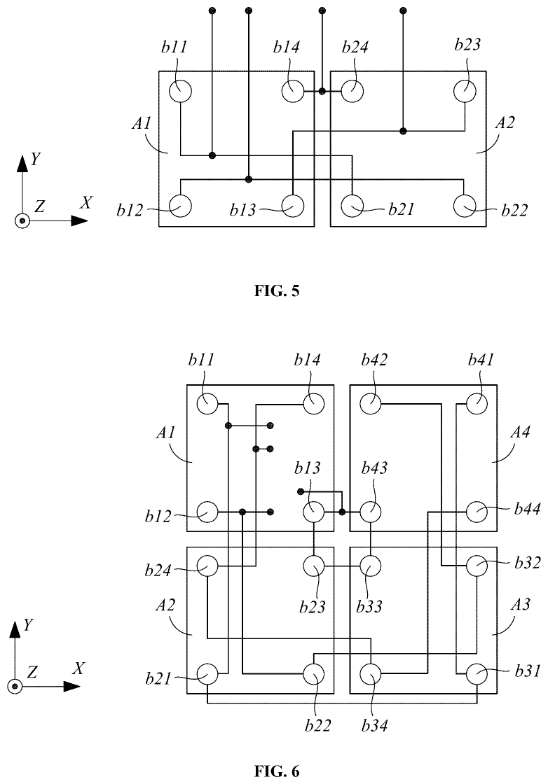

As shown in FIG. 4, FIG. 5 and FIG. 6, when current i is introduced into a Hall unit and a magnetic field is applied to the Hall unit, the charges in the current are deflected by a Lorentz force, thus moving towards one electrode and away from another electrode. The electrode towards which the charges move can be defined as a charge deflection electrode, and the electrode away from which the charges move can be defined as a charge repulsion electrode.

For example, in FIG. 4, when current i flows from electrode b01 to electrode b03 of Hall unit A0, and a magnetic field perpendicular to the paper plane and pointing inward (−Z direction) is applied to the Hall unit, electrode b04 can be defined as the charge deflection electrode, and electrode b02 can be defined as the charge repulsion electrode. Since the accumulation of charges is related to the strength of the magnetic field applied to Hall unit A0, electrodes b04 and b02 can form outputs carrying magnetic field-related detection signals at this time.

The charge deflection electrode b04 at Hall unit A0 is used to form a first Hall output, and the charge repulsion electrode b02 at Hall unit A0 is used to form a second Hall output. Furthermore, the sensing assembly uses the first Hall output and the second Hall output as a signal output of the corresponding sensing element. When multiple sensing elements are included in a single sensing assembly, outputs of several Hall units collectively serve as the output of the corresponding sensing assembly.

As shown in FIG. 5, a single sensing element can comprise two Hall units (for example, a first Hall unit A1 and a second Hall unit A2). The charge deflection electrodes (for example, electrodes b14 and b24) of the Hall units are coupled, the charge repulsion electrodes (for example, electrodes b12 and b22) of the Hall units are coupled, power supply electrodes (for example, electrodes b11 and b21) of the Hall units are coupled, and reference electrodes (for example, electrodes b13 and b23, used for grounding) of the Hall units are coupled.

As shown in FIG. 6, a single sensing element can comprise four Hall units (for example, a first Hall unit A1, a second Hall unit A2, a third Hall unit A3, and a fourth Hall unit A4). The charge deflection electrodes (for example, electrodes b14, b24, b34, and b44) of the Hall units are coupled, the charge repulsion electrodes (for example, electrodes b12, b22, b32, and b42) of the Hall units are coupled, power supply electrodes (for example, electrodes b11, b21, b31, and b41) of the Hall units are coupled, and reference electrodes (for example, electrodes b13, b23, b33, and b43, used for grounding) of the Hall units are coupled.

The two configuration schemes shown in FIG. 5 and FIG. 6 can make driving current directions in adjacent Hall units perpendicular to each other. The orthogonality of driving currents can allow the zero-point drift at the Hall units to be mutually cancelled, optimizing the performance of the Hall units themselves; wherein, the zero-point drift may be caused by uneven production processes.

In technical solutions provided by the present application, the sensing elements, especially several sensing elements set in a same sensing assembly, can be configured to have a same structure, thereby ensuring uniform magnetic field detection in various directions.

In an embodiment, the first sensing element 211, the second sensing element 212, the third sensing element 311, the fourth sensing element 312, the fifth sensing element 411, the sixth sensing element 412, the seventh sensing element 511 and the eighth sensing element 512 are configured to have a same structure.

As shown in FIG. 7, FIG. 14, and FIG. 16, the first sensing assembly 200 comprises a first magnetic flux concentrator 201. The first magnetic flux concentrator 201 includes a symmetry axis passing through a geometric center of the first magnetic flux concentrator and extending along the second direction D2, and the first sensing element 211 and the second sensing element 212 are symmetrical with respect to the symmetry axis. As such, more uniform sensitivity can be obtained on both sides of the second direction D2; when the first direction D1 is perpendicular to the second direction D2, this effect is more pronounced.

The projections of the first sensing element 211 and the second sensing element 212 on the first magnetic flux concentrator 201 at least partially overlap with the extension surface of the first magnetic flux concentrator 201. As such, the magnetic field direction at the sensing elements can be deflected by the adjustment of the magnetic flux concentrator, increasing the field strength of the magnetic field that the sensing elements can obtain.

The second sensing assembly 300 comprises a second magnetic flux concentrator 301. The second magnetic flux concentrator 301 includes a symmetry axis passing through a geometric center of the second magnetic flux concentrator and extending along the first direction D1, and the third sensing element 311 and the fourth sensing element 312 are symmetrical with respect to the symmetry axis. As such, more uniform sensitivity can be obtained on both sides of the first direction D1.

The projections of the third sensing element 311 and the fourth sensing element 312 on the second magnetic flux concentrator 301 at least partially overlap with the extension surface of the second magnetic flux concentrator 301.

The third sensing assembly 400 comprises a third magnetic flux concentrator 401. The third magnetic flux concentrator 401 includes a symmetry axis passing through a geometric center of the third magnetic flux concentrator and extending along the second direction D2, and the fifth sensing element 411 and the sixth sensing element 412 are symmetrical with respect to the symmetry axis. As such, more uniform sensitivity can be obtained on both sides of the second direction D2.

The projections of the fifth sensing element 411 and the sixth sensing element 412 on the third magnetic flux concentrator 401 at least partially overlap with the extension surface of the third magnetic flux concentrator 401.

The fourth sensing assembly 500 comprises a fourth magnetic flux concentrator 501. The fourth magnetic flux concentrator 501 includes a symmetry axis passing through a geometric center of the fourth magnetic flux concentrator and extending along the first direction D1, and the seventh sensing element 511 and the eighth sensing element 512 are symmetrical with respect to the symmetry axis. As such, more uniform sensitivity can be obtained on both sides of the first direction D1.

The projections of the seventh sensing element 511 and the eighth sensing element 512 on the fourth magnetic flux concentrator 501 at least partially overlap with the extension surface of the fourth magnetic flux concentrator 501.

As shown in the technical solutions in FIG. 7 and FIG. 14, the sensing elements belonging to a same sensing assembly can be arranged at edges of the corresponding magnetic flux concentrator in a direction of in the opposite direction of the direction.

For example, in the first sensing assembly 200, the first sensing element 211 is arranged at an edge of the first magnetic flux concentrator 201 in a Y direction (or the first direction D1); the second sensing element 212 is arranged at an edge of the first magnetic flux concentrator 201 in the opposite direction of the Y direction.

In the second sensing assembly 300, the third sensing element 311 is arranged at an edge of the second magnetic flux concentrator 301 in the opposite direction of an X direction (or the second direction D2); the fourth sensing element 312 is arranged at an edge of the second magnetic flux concentrator 301 in the X direction.

In the third sensing assembly 400, the fifth sensing element 411 is arranged at an edge of the third magnetic flux concentrator 401 in a Y direction; the sixth sensing element 412 is arranged at an edge of the third magnetic flux concentrator 401 in the opposite direction of the Y direction.

In the fourth sensing assembly 500, the seventh sensing element 511 is arranged at an edge of the fourth magnetic flux concentrator 501 in the opposite direction of an X direction; the eighth sensing element 512 is arranged at an edge of the fourth magnetic flux concentrator 501 in the X direction.

As shown in the technical solution in FIG. 16, the sensing elements belonging to a same sensing assembly can be arranged at edges of the corresponding magnetic flux concentrator in two mutually perpendicular directions. In particular, they can be arranged on sides away from a geometric center of the carrying surface.

For example, in the first sensing assembly 200, the first sensing element 211 is arranged at an edge of the first magnetic flux concentrator 201 in a Y direction; the second sensing element 212 is arranged at an edge of the first magnetic flux concentrator 201 in the opposite direction of the X direction.

In the second sensing assembly 300, the third sensing element 311 is arranged at an edge of the second magnetic flux concentrator 301 in the opposite direction of the X direction; the fourth sensing element 312 is arranged at an edge of the second magnetic flux concentrator 301 in the opposite direction of the Y direction.

In the third sensing assembly 400, the fifth sensing element 411 is arranged at an edge of the third magnetic flux concentrator 401 in the X direction; the sixth sensing element 412 is arranged at an edge of the third magnetic flux concentrator 401 in the opposite direction of the Y direction.

In the fourth sensing assembly 500, the seventh sensing element 511 is arranged at an edge of the fourth magnetic flux concentrator 501 in the Y direction; the eighth sensing element 512 is arranged at an edge of the fourth magnetic flux concentrator 501 in the X direction.

As shown in FIG. 7, FIG. 8, FIG. 14, and referring to FIG. 16, when the magnetic sensor 100 is close to a magnetic device to be measured 900, at least in a first state, at least one of the first sensing assembly 200, the second sensing assembly 300, the third sensing assembly 400 and the fourth sensing assembly 500 is close to a first magnetic pole N of the magnetic device to be measured 900. For example, in the embodiment provided in FIG. 7 and FIG. 8, the first sensing assembly 200 and the second sensing assembly 300 are close to the first magnetic pole N; after the magnetic device to be measured 900 rotates 180 degrees around a geometric center of the magnetic device to be measured, the third sensing assembly 400 and the fourth sensing assembly 500 are close to the first magnetic pole N. For example, in the embodiment provided in FIG. 14, the third sensing assembly 400 and the fourth sensing assembly 500 are close to the first magnetic pole N; after the magnetic device to be measured 900 rotates 180 degrees around a geometric center of the magnetic device to be measured, the first sensing assembly 200 and the second sensing assembly 300 are close to the first magnetic pole N.

When the magnetic sensor 100 is close to a magnetic device to be measured 900, at least in a first state, at least another one of the first sensing assembly 200, the second sensing assembly 300, the third sensing assembly 400 and the fourth sensing assembly 500 is relatively far from the first magnetic pole N of the magnetic device to be measured 900. For example, in the embodiment provided in FIG. 7 and FIG. 8, the third sensing assembly 400 and the fourth sensing assembly 500 are relatively far from the first magnetic pole N. For example, in the embodiment provided in FIG. 14, the first sensing assembly 200 and the second sensing assembly 300 are relatively far from the first magnetic pole N.

For a magnetic device to be measured 900 prepared as a magnetic monopole, the entirety of the magnetic device to be measured can be viewed as a kind of the first magnetic pole, so the technical solutions can be further explained as: there exists at least one state where one of the sensing assemblies is closer to the magnetic device to be measured 900, while at least another one is farther from the magnetic device to be measured 900.

Since the two sensing assemblies have different positions relative to the first magnetic pole N in at least one state, two detection signals formed by the magnetic field components in sensing directions of the two sensing assemblies sensed by the two sensing assemblies differ due to different distances between the two sensing assemblies and the first magnetic pole, thus detection signals along the sensing direction can be selectively retained; correspondingly, the magnetic field components in other directions are usually shown as uniformly distributed interference magnetic fields, and the detection signals formed by the interference magnetic fields at the two sensing assemblies are approximately the same, so they can be eliminated by calculation.

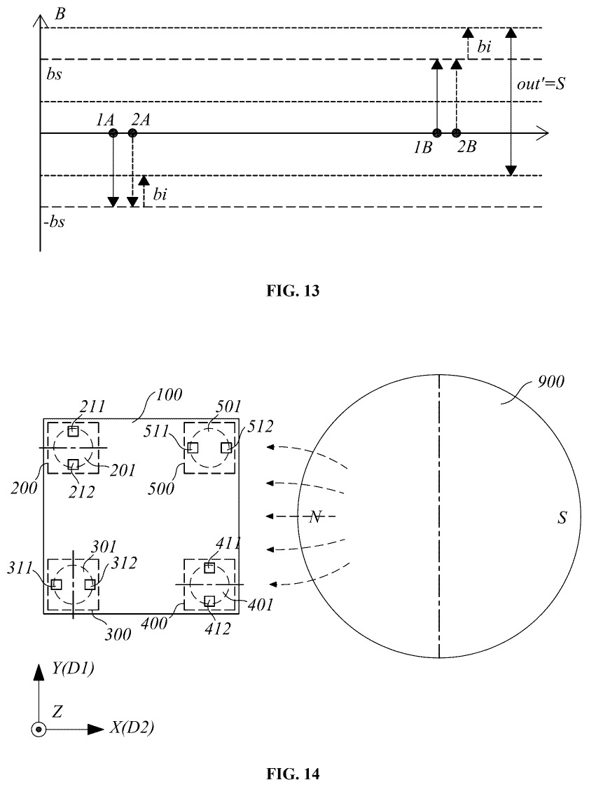

As shown in figures from FIG. 7 to FIG. 19, among the first sensing assembly 200, the second sensing assembly 300, the third sensing assembly 400 and the fourth sensing assembly 500, a sensing signal generated by the sensing elements on one side of a Y direction and a sensing signal generated by the sensing elements on another side of the opposite direction of the Y direction are used to calculate and generate a first output signal.

Herein, being on a certain side of the Y direction or the opposite direction of the Y direction can be defined with respect to a geometric center of the sensing assembly, and can use “the symmetry axis passing through a geometric center of the sensing assembly and extending in a direction perpendicular to the Y direction” as a reference line. Sensing elements on this reference line do not belong to a certain side of either the Y direction or the opposite direction of the Y direction.

Among the first sensing assembly 200, the second sensing assembly 300, the third sensing assembly 400 and the fourth sensing assembly 500, a sensing signal generated by the sensing elements on one side of an X direction and a sensing signal generated by the sensing elements on another side of the opposite direction of the X direction are used to calculate and generate a second output signal.

Herein, being on one side of a certain side of the X direction or the opposite direction of the X direction can be defined with respect to a geometric center of the sensing assembly, and can use “the symmetry axis passing through a geometric center of the sensing assembly and extending in a direction perpendicular to the X direction” as a reference line. Sensing elements on this reference line do not belong to a certain side of either the X direction or the opposite direction of the X direction.

At least one of the first output signal and the second output signal is used to calculate and generate motion state data of a magnetic device to be measured 900. The motion state data can be specifically calculated and generated through methods such as waveform fitting and period division, which will not be elaborated here. Specifically, the motion state data includes rotation angle data.

The X direction and the Y direction form the first angle. The angle between the X direction and the Y direction is equal to the angle between the first direction D1 and the second direction D2. Preferably, the first angle is 90 degrees.

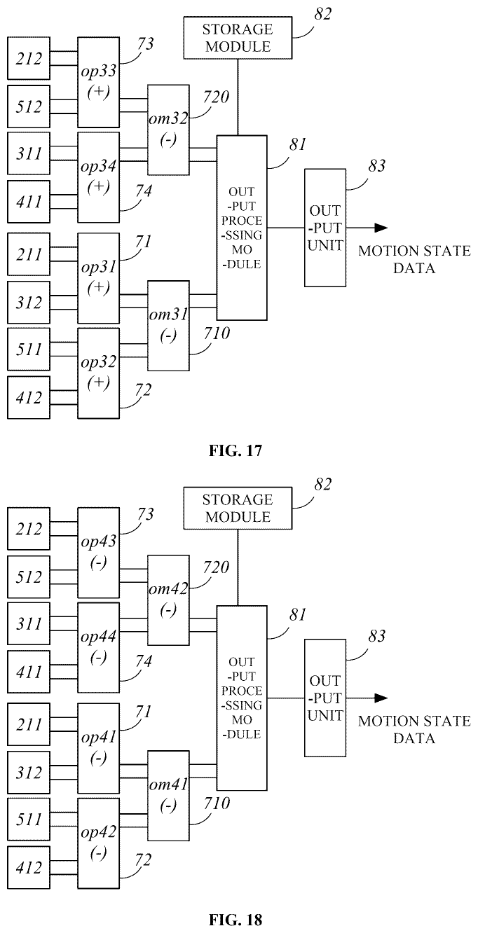

As shown in figures from FIG. 7 to FIG. 11, and FIG. 16, FIG. 17, the magnetic sensor 100 is provided on one side of a magnetic device to be measured 900 in a third direction. Wherein, the third direction can be a Z direction or a height direction of the magnetic device to be measured 900. The third direction is perpendicular to both the first direction D1 and the second direction D2.

A geometric center of the substrate 101 is aligned with a geometric center of the magnetic device to be measured 900. As such, the magnetic sensor 100 can uniformly sense state changes of the magnetic device to be measured 900; especially sensing the changes in a rotation angle of the magnetic device to be measured 900.

In a first state, the first sensing assembly 200 and the second sensing assembly 300 are symmetrically arranged with respect to the third sensing assembly 400 and the fourth sensing assembly 500 relative to a magnetic pole interface extending along a Y direction. As shown in an embodiment in figures from FIG. 7 to FIG. 11, the symmetry relationship is limited to the symmetry of the positioning of the sensing assemblies; as shown in an embodiment in FIG. 16, the symmetry relationship includes the symmetry of the positioning of the sensing assemblies and the symmetry of the arrangement of sensing elements within the sensing assemblies.

Among the first sensing assembly 200, the second sensing assembly 300, the third sensing assembly 400 and the fourth sensing assembly 500, a sensing signal generated by the sensing elements on one side of the Y direction and the sensing signals generated by the sensing elements on another side of the opposite direction of the Y direction are used to calculate and generate a first output signal.

For example, in an embodiment shown in figures from FIG. 7 to FIG. 11, the first sensing element 211 is the sensing element on one side of the Y direction in the first sensing assembly 200, the fifth sensing element 411 is the sensing element on one side of the Y direction in the third sensing assembly 400; the second sensing element 212 is the sensing element on another side of the opposite direction of the Y direction in the first sensing assembly 200, the sixth sensing element 412 is the sensing element on another side of the opposite direction of the Y direction in the third sensing assembly 400. The above sensing elements are used to calculate and generate a first output signal om11.

For another example, in an embodiment shown in FIG. 16 and FIG. 17, the first sensing element 211 is the sensing element on one side of the Y direction in the first sensing assembly 200, the seventh sensing element 511 is the sensing element on one side of the Y direction in the fourth sensing assembly 500; the fourth sensing element 312 is the sensing element on another side of the opposite direction of the Y direction in the second sensing assembly 300, the sixth sensing element 412 is the sensing element on another side of the opposite direction of the Y direction in the third sensing assembly 400. The above sensing elements are used to calculate and generate another first output signal om31.

Among the first sensing assembly 200, the second sensing assembly 300, the third sensing assembly 400 and the fourth sensing assembly 500, a sensing signal generated by the sensing elements on one side of an X direction and a sensing signal generated by the sensing elements on another side of the opposite direction of the X direction are used to calculate and generate a second output signal.

For example, in an embodiment shown in figures from FIG. 7 to FIG. 11, the fourth sensing element 312 is the sensing element on one side of the X direction in the second sensing assembly 300, the eighth sensing element 512 is the sensing element on one side of the X direction in the fourth sensing assembly 500; the third sensing element 311 is the sensing element on another side of the opposite direction of the X direction in the second sensing assembly 300, the seventh sensing element 511 is the sensing element on another side of the opposite direction of the X direction in the fourth sensing assembly 500. The above sensing elements are used to calculate and generate a second output signal om12.

For another example, in an embodiment shown in FIG. 16 and FIG. 17, the eighth sensing element 512 is the sensing element on one side of the X direction in the fourth sensing assembly 500, the fifth sensing element 411 is the sensing element on one side of the X direction in the third sensing assembly 400; the second sensing element 212 is the sensing element on another side of the opposite direction of the X direction in the first sensing assembly 200, the third sensing element 311 is the sensing element on another side of the X direction in the second sensing assembly 300. The above sensing elements are used to calculate and generate another second output signal om32.

At least one of the first output signal and the second output signal is used to calculate and generate motion state data of the magnetic device to be measured 900. Specifically, the motion state data includes rotation angle data.

The X direction and the Y direction form the first angle. Preferably, the first angle is 90 degrees.

In an embodiment shown in figures from FIG. 7 to FIG. 11, the first direction D1 is parallel to the Y direction, and the second direction D2 is parallel to the X direction.

In an embodiment shown in FIG. 16 and FIG. 17, the X direction points to a middle direction between the first direction D1 and the second direction D2; an angle between the X direction and the first direction D1 is equal to an angle between the X direction and the second direction D2.

Among the first sensing assembly 200, the second sensing assembly 300, the third sensing assembly 400, and the fourth sensing assembly 500, the sensing elements on one side of the Y direction are used to generate a first sensing signal and a second sensing signal, and the sensing elements on another side of the opposite direction of the Y direction are used to generate a third sensing signal and a fourth sensing signal.

The first sensing signal and the third sensing signal are used to perform a first operation to form a first intermediate signal, and the second sensing signal and the fourth sensing signal are used to perform a first operation to form a second intermediate signal.

For example, in an embodiment shown in figures from FIG. 7 to FIG. 11, the first sensing element 211 is used to generate the first sensing signal, the second sensing element 212 is used to generate the third sensing signal, so the two perform the first operation to form a first intermediate signal op11. In an embodiment, the first operation is a superposition operation.

The fifth sensing element 411 is used to generate the second sensing signal, the sixth sensing element 412 is used to generate the fourth sensing signal, so the two perform the first operation to form a second intermediate signal op12. In an embodiment, the first operation is a superposition operation.

For another example, in the embodiment shown in FIG. 16 and FIG. 17, the first sensing element 211 is used to generate the first sensing signal, the fourth sensing element 312 is used to generate the third sensing signal, so the two perform the first operation to form another first intermediate signal op31. In an embodiment, the first operation is a superposition operation.

The seventh sensing element 511 is used to generate the second sensing signal, the sixth sensing element 412 is used to generate the fourth sensing signal, so the two perform the first operation to form another second intermediate signal op32. In an embodiment, the first operation is a superposition operation.

The first intermediate signal and the second intermediate signal are used to perform a second operation to form a first output signal.

For example, in an embodiment shown in figures from FIG. 7 to FIG. 11, the first intermediate signal op11 and the second intermediate signal op12 are used to perform the second operation to form a first output signal om11. In an embodiment, the second operation is a differential operation; when performing the second operation, the difference between the first intermediate signal op11 and the second intermediate signal op12 is taken.

For another example, in an embodiment shown in FIG. 16 and FIG. 17, another first intermediate signal op31 and another second intermediate signal op32 are used to perform the second operation to form another first output signal om31. In an embodiment, the second operation is a differential operation.

As such, the sensing signals of the sensing elements at both ends of the Y direction can be comprehensively considered, and the two sets of sensing signals (i.e., intermediate signals) can be compared and judged, thereby obtaining magnetic field change sensing over a wider range, and this sensing can be completed with only 4 sensing elements.

Among the first sensing assembly 200, the second sensing assembly 300, the third sensing assembly 400, and the fourth sensing assembly 500, the sensing elements on one side of the X direction are used to generate a fifth sensing signal and a sixth sensing signal, and the sensing elements on another side of the opposite direction of the X direction are used to generate a seventh sensing signal and an eighth sensing signal.

The fifth sensing signal and the seventh sensing signal are used to perform a first operation to form a third intermediate signal, and the sixth sensing signal and the eighth sensing signal are used to perform a first operation to form a fourth intermediate signal.

For example, in an embodiment shown in figures from FIG. 7 to FIG. 11, the fourth sensing element 312 is used to generate the fifth sensing signal, the third sensing element 311 is used to generate the seventh sensing signal, so the two perform the first operation to form a third intermediate signal op13. In an embodiment, the first operation is a superposition operation.

The eighth sensing element 512 is used to generate the sixth sensing signal, the seventh sensing element 511 is used to generate the eighth sensing signal, so the two perform the first operation to form a fourth intermediate signal op14. In an embodiment, the first operation is a superposition operation.

For another example, in the embodiment shown in FIG. 16 and FIG. 17, the eighth sensing element 512 is used to generate the fifth sensing signal, the second sensing element 212 is used to generate the seventh sensing signal, so the two perform the first operation to form another third intermediate signal op33. In an embodiment, the first operation is a superposition operation.

The fifth sensing element 411 is used to generate the sixth sensing signal, the third sensing element 311 is used to generate the eighth sensing signal, so the two perform the first operation to form another fourth intermediate signal op34. In an embodiment, the first operation is a superposition operation.

The third intermediate signal and the fourth intermediate signal are used to perform a second operation to form a second output signal.

For example, in an embodiment shown in figures from FIG. 7 to FIG. 11, the third intermediate signal op13 and the fourth intermediate signal op14 are used to perform the second operation to form a second output signal om12. In an embodiment, the second operation is a differential operation.

For another example, in an embodiment shown in FIG. 16 and FIG. 17, another third intermediate signal op33 and another fourth intermediate signal op34 are used to perform the second operation to form another second output signal om32. In an embodiment, the second operation is a differential operation.

As such, the sensing signals of the sensing elements at both ends of the X direction can be comprehensively considered, and the two sets of sensing signals (i.e., intermediate signals) can be compared and judged, thereby obtaining magnetic field change sensing over a wider range, and this sensing can be completed with only 4 sensing elements.

For a first embodiment provided in figures from FIG. 7 to FIG. 11, in a first state, the first sensing assembly 200 and the second sensing assembly 300 are symmetrically arranged with respect to the third sensing assembly 400 and the fourth sensing assembly 500 relative to a magnetic pole interface extending along the first direction D1.

In the first embodiment, in the first state: the first direction D1, Y direction, magnetic pole interface extension direction, spacing direction of the first sensing element 211 and the second sensing element 212, and spacing direction of the fifth sensing element 411 and the sixth sensing element 412 are unified.

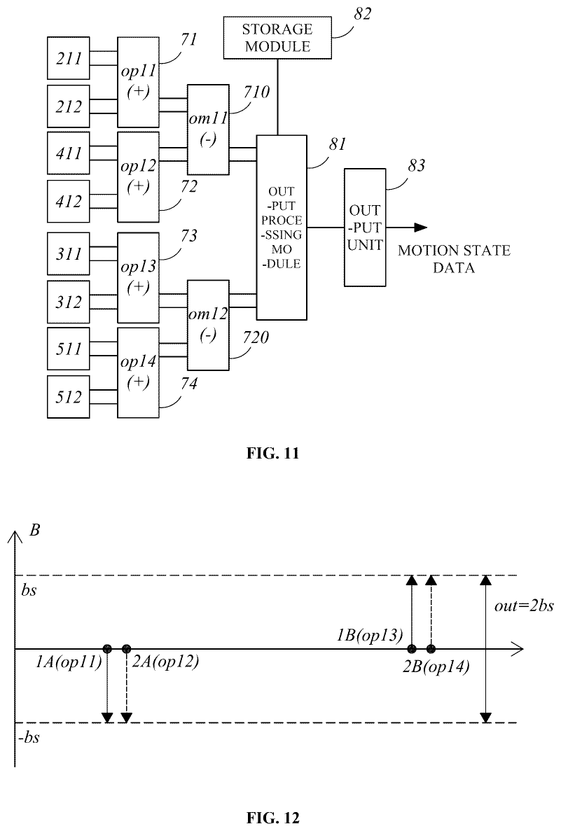

Based on this, combined with FIG. 11, the first sensing element 211 is used to generate a first sensing signal, the second sensing element 212 is used to generate a third sensing signal. The fifth sensing element 411 is used to generate a second sensing signal, the sixth sensing element 412 is used to generate a fourth sensing signal.

The fourth sensing element 312 is used to generate a fifth sensing signal, the third sensing element 311 is used to generate a seventh sensing signal. The eighth sensing element 512 is used to generate a sixth sensing signal, the seventh sensing element 511 is used to generate an eighth sensing signal.

Correspondingly, the present application also provides a state detection device, comprising the magnetic sensor 100 in the first embodiment. The state detection device also comprises:

A first intermediate signal operation module 71, coupled to the first sensing element 211 and the second sensing element 212. The first intermediate signal operation module 71 is used to perform a first operation on sensing signals from the first sensing element 211 and the second sensing element 212 to form a first intermediate signal.

A second intermediate signal operation module 72, coupled to the fifth sensing element 411 and the sixth sensing element 412. The second intermediate signal operation module 72 is used to perform a first operation on sensing signals from the fifth sensing element 411 and the sixth sensing element 412 to form a second intermediate signal.

A third intermediate signal operation module 73, coupled to the third sensing element 311 and the fourth sensing element 312. The third intermediate signal operation module 73 is used to perform a first operation on sensing signals from the third sensing element 311 and the fourth sensing element 312 to form a third intermediate signal.

A fourth intermediate signal operation module 74, coupled to the seventh sensing element 511 and the eighth sensing element 512. The fourth intermediate signal operation module 74 is used to perform a first operation on sensing signals from the seventh sensing element 511 and the eighth sensing element 512 to form a fourth intermediate signal.

A first output signal operation module 710, coupled to the first intermediate signal operation module 71 and the second intermediate signal operation module 72. The first output signal operation module 710 is used to perform a second operation on intermediate signals from the first intermediate signal operation module 71 and the second intermediate signal operation module 72 to form a first output signal om11.

A second output signal operation module 720, coupled to the third intermediate signal operation module 73 and the fourth intermediate signal operation module 74. The second output signal operation module 720 is used to perform a second operation on intermediate signals from the third intermediate signal operation module 73 and the fourth intermediate signal operation module 74 to form a second output signal om12.

An output processing module 81, coupled to the first output signal operation module 710 and the second output signal operation module 720. The output processing module 81 is used to calculate and generate motion state data of a magnetic device to be measured, especially to calculate and generate rotation angle data. The output processing module 81 is used to perform operations on the first output signal om11 and the second output signal om12 from the first output signal operation module 710 and the second output signal operation module 720 to generate at least rotation angle data.

A storage module 82, coupled to the output processing module 81. The storage module 82 is used to store at least correction information for the rotation angle data.

In an embodiment, the state detection device also includes an output unit 83 coupled to the output processing module 81, used to produce a final device output.

As shown in figures from FIG. 7 to FIG. 10, in the first state, the first sensing assembly 200 and the fourth sensing assembly 500 are symmetrically arranged with respect to a plane of the magnetic pole interface of a magnetic device to be measured 900.

In the first state, for the magnetic field components along a Z direction and the opposite direction of the Z direction, the magnetic field direction at the first sensing assembly 200 is arranged in the opposite direction of the Z direction, while at the fourth sensing assembly 500 the magnetic field direction is arranged in the Z direction. The magnetic field components in the Z direction or the opposite direction of the Z direction formed at the first sensing assembly and the fourth sensing assembly are essentially equal in absolute value, thus enabling detection signals to retain their original values when superimposed. For magnetic field components in an X direction at the magnetic sensor 100, the magnetic field directions at both the first sensing assembly 200 and the fourth sensing assembly 500 are arranged in the X direction, and the magnetic field components in the X direction formed at the first sensing assembly and the fourth sensing assembly are essentially equal, thus enabling mutual cancellation or superposition.

Referring to FIG. 9, even if a second magnetic flux concentrator 301 causes the magnetic field in the Z direction to deflect along an X direction, because the second sensing assembly 300 comprises the third sensing element 311 and the fourth sensing element 312 arranged at intervals along the X direction on both sides of the second magnetic flux concentrator 301, the deflected magnetic field components along the X direction can be differentially weakened due to their opposite directions. Preferably, the third sensing element 311 and the fourth sensing element 312 can be symmetrical with respect to a projection on a side of the sensing elements relative to a symmetry axis of the second magnetic flux concentrator 301 along a Y direction, which can essentially achieve complete cancellation of the deflected magnetic field components. In an embodiment, the Y direction is parallel to an extension surface of the second magnetic flux concentrator 301 and perpendicular to the X direction.

Referring to FIG. 10, even if a second magnetic flux concentrator 301 causes the magnetic field in an X direction to deflect along the Z direction, because the second sensing assembly 300 comprises the third sensing element 311 and the fourth sensing element 312 arranged at intervals along the X direction on both sides of the second magnetic flux concentrator 301, the deflected magnetic field components along the Z direction can be differentially weakened due to their opposite directions. Preferably, the third sensing element 311 and the fourth sensing element 312 can be axisymmetric with respect to a projection on a side of the sensing elements relative to a symmetry axis of the second magnetic flux concentrator 301 along a Y direction, which can essentially achieve complete cancellation of the deflected magnetic field components. In an embodiment, the Y direction is parallel to an extension surface of the second magnetic flux concentrator 301 and perpendicular to the X direction.

In the first state, due to the second magnetic flux concentrator 301, the magnetic field components along the X direction do not pass through an area between the third sensing element 311 and the fourth sensing element 312, forming a “magnetic field vacuum area”, achieving the effect of shielding magnetic field interference in non-sensing directions.

As shown in figures from FIG. 7 to FIG. 13, the magnetic device to be measured 900 is provided on a side of the magnetic sensor 100 in a third direction. In the first state, the first sensing assembly 200 and the second sensing assembly 300 are close to a first magnetic pole N, while the third sensing assembly 400 and the fourth sensing assembly 500 are far from the first magnetic pole N. The first sensing assembly 300 comprises the first sensing element 211 and the second sensing element 212 spaced apart along the Y direction. The second sensing assembly 300 comprises the third sensing element 311 and the fourth sensing element 312 spaced apart along the X direction. The third sensing assembly 400 comprises the fifth sensing element 411 and the sixth sensing element 412 spaced apart along the Y direction. The fourth sensing assembly 500 comprises the seventh sensing element 511 and the eighth sensing element 512 spaced apart along the X direction.

Defining the third direction (for example, the Z direction) as a positive direction of the magnetic field strength, intermediate signals 1A and 2A are formed at the sensing assemblies relatively close to the first magnetic pole N. Without considering interference, the intermediate signals 1A and 2A have a reverse magnetic field strength of −bs, and with interference, the intermediate signals have a reverse magnetic field strength of (−bs+bi) including interference magnetic field strength bi. For example, in a state shown in FIG. 7, an intermediate signal 1A is a first intermediate signal op11 formed by the first sensing element 211 and the second sensing element 212; an intermediate signal 2A is a third intermediate signal op13 formed by the third sensing element 311 and the fourth sensing element 312.

Intermediate signals 1B and 2B are formed at the sensing assemblies relatively far from the first magnetic pole N. Without considering interference, the intermediate signals 1B and 2B have a forward magnetic field strength of +bs, and with interference, the intermediate signals 1B and 2B have a forward magnetic field strength of (+bs+bi) including interference magnetic field strength bi. For example, in a state shown in FIG. 7, an intermediate signal 1B is a second intermediate signal op12 formed by the fifth sensing element 411 and the sixth sensing element 412; an intermediate signal 2B is a fourth intermediate signal op14 formed by the seventh sensing element 511 and the eighth sensing element 512.

Since the direction and value of the interference magnetic field strength embodied in the intermediate signals are the same, the interference magnetic field can be removed through calculation. Thus, interference shielding can be achieved by simply configuring sensing elements, reducing the cost and energy consumption of the magnetic sensor.

Based on this, if the second operation is a differential operation, then the first intermediate signal op11 corresponding to intermediate signal 1A and the second intermediate signal op12 corresponding to intermediate signal 1B are differentially operated to form the first output signal om11 with a magnetic field strength of 2bs; the third intermediate signal op13 corresponding to intermediate signal 2A and the fourth intermediate signal op14 corresponding to intermediate signal 2B are differentially operated to form the second output signal om12 with a magnetic field strength of 2bs.

On one hand, interference magnetic fields can be removed during the differential operation process; on the other hand, based on the difference between the positioning of the first sensing element 211, the second sensing element 212, the fifth sensing element 411, and the sixth sensing element 412 corresponding to the first output signal om11, and the positioning of the third sensing element 311, the fourth sensing element 312, the seventh sensing element 511, and the eighth sensing element 512 corresponding to the second output signal om12, it is possible to effectively sense data containing motion states of the magnetic device to be measured, especially data related to a rotation angle of the magnetic device to be measured.

Moreover, if the first operation is a superposition operation, then the superposition of outputs of sensing elements in a same sensing assembly can cause the magnetic field components parallel to a substrate plane (for example, an XY plane) in FIG. 10 to be cancelled, so the sensing assembly only generates output for the magnetic field components perpendicular to the substrate plane.

If the first operation is a differential operation, then the influence of the interference magnetic field can be excluded in the process of generating intermediate signals. If the second operation is a superposition operation, then the intermediate signals formed by four sensing elements along a same spacing direction but at different positions can be superimposed to obtain further sensing signals.

For a third embodiment provided in FIG. 16 and FIG. 17, in a first state, the first sensing assembly 200 and the second sensing assembly 300 are symmetrically arranged with respect to the third sensing assembly 400 and the fourth sensing assembly 500 relative to a magnetic pole interface extending along a Y direction.

The Y direction points to a middle direction of the first direction D1 and the opposite direction of the second direction D2. An X direction points to a middle direction of the first direction D1 and the second direction D2.

In the third embodiment, in the first state: the Y direction and the magnetic pole interface extension direction are unified, the first direction D1, the spacing direction of the first sensing element 211 and the second sensing element 212, and the spacing direction of the fifth sensing element 411 and the sixth sensing element 412 are unified; and the aforementioned two directions are set at a second angle. Preferably, the second angle is half of the first angle. Preferably, the first angle is 90 degrees and the second angle is 45 degrees.

Based on this, combined with FIG. 17, the first sensing element 211 is used to generate a first sensing signal, the fourth sensing element 312 is used to generate a third sensing signal. The seventh sensing element 511 is used to generate a second sensing signal, the sixth sensing element 412 is used to generate a fourth sensing signal.

The eighth sensing element 512 is used to generate a fifth sensing signal, the second sensing element 212 is used to generate a seventh sensing signal. The fifth sensing element 411 is used to generate a sixth sensing signal, the third sensing element 311 is used to generate an eighth sensing signal.

Correspondingly, the present application also provides a state detection device, comprising the magnetic sensor 100 in the third embodiment. The state detection device also comprises:

A first intermediate signal operation module 71, coupled to the first sensing element 211 and the fourth sensing element 312. The first intermediate signal operation module 71 is used to perform a first operation on sensing signals from the first sensing element 211 and the fourth sensing element 312 to form a first intermediate signal.

A second intermediate signal operation module 72, coupled to the seventh sensing element 511 and the sixth sensing element 412. The second intermediate signal operation module 72 is used to perform a first operation on sensing signals from the seventh sensing element 511 and the sixth sensing element 412 to form a second intermediate signal.

A third intermediate signal operation module 73, coupled to the second sensing element 212 and the eighth sensing element 512. The third intermediate signal operation module 73 is used to perform a first operation on sensing signals from the second sensing element 212 and the eighth sensing element 512 to form a third intermediate signal.

A fourth intermediate signal operation module 74, coupled to the third sensing element 311 and the fifth sensing element 411. The fourth intermediate signal operation module 74 is used to perform a first operation on sensing signals from the third sensing element 311 and the fifth sensing element 411 to form a fourth intermediate signal.

A first output signal operation module 710, coupled to the first intermediate signal operation module 71 and the second intermediate signal operation module 72. The first output signal operation module 710 is used to perform a second operation on intermediate signals from the first intermediate signal operation module 71 and the second intermediate signal operation module 72 to form a first output signal om31.

A second output signal operation module 720, coupled to the third intermediate signal operation module 73 and the fourth intermediate signal operation module 74. The second output signal operation module 720 is used to perform a second operation on intermediate signals from the third intermediate signal operation module 73 and the fourth intermediate signal operation module 74 to form a second output signal om32.

An output processing module 81, coupled to the first output signal operation module 710 and the second output signal operation module 720. The output processing module 81 is used to calculate and generate motion state data of a magnetic device to be measured, especially to calculate and generate rotation angle data. The output processing module 81 is used to perform operations on the first output signal om31 and the second output signal om32 from the first output signal operation module 710 and the second output signal operation module 720 to generate at least rotation angle data.

A storage module 82, coupled to the output processing module 81. The storage module 82 is used to store at least correction information for the rotation angle data.

In an embodiment, the state detection device also includes an output unit 83 coupled to the output processing module 81, used to produce a final device output.

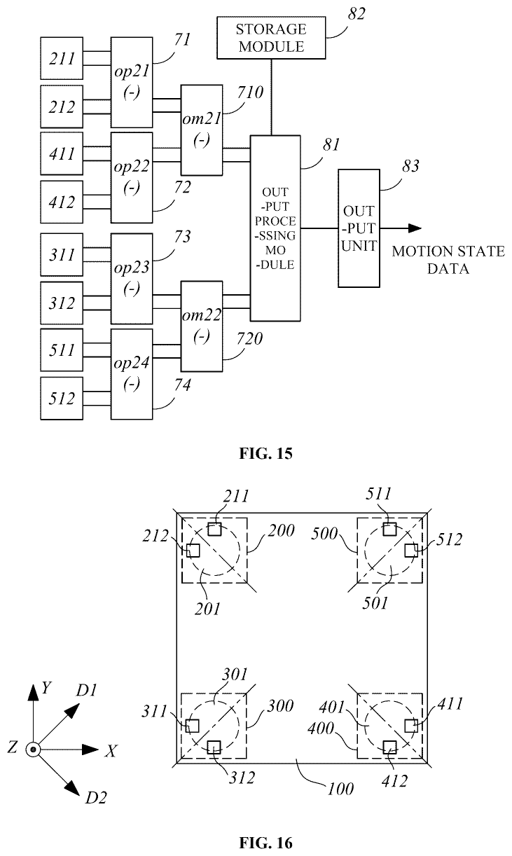

As shown in FIG. 14, FIG. 15, FIG. 16 and FIG. 18, the magnetic sensor 100 is provided on one side of the magnetic device to be measured 900 in a width direction. Wherein, the width direction can be any direction parallel to a plane containing the first direction D1 and the second direction D2, or any direction parallel to a plane containing an X direction and Y direction, or any direction perpendicular to a third direction or Z direction. In an embodiment, the magnetic sensor 100 is provided on the side of the magnetic device to be measured 900 along the X direction.

The magnetic sensor 100 is flush with the magnetic device to be measured 900 in a third direction. The magnetic sensor 100 and the magnetic device to be measured 900 are in a same position in a third direction. The magnetic sensor 100 is at a same height as the magnetic device to be measured 900 in a third direction. The third direction is perpendicular to both the first direction and the second direction.

Preferably, the magnetic sensor 100 can be aligned with the magnetic device to be measured 900 in the third direction through the magnetic flux concentrator. This can make the magnetic concentration effect in the third direction more uniform.

In a first state, the first sensing assembly 200 and the second sensing assembly 300 are relatively far from a first magnetic pole N of the magnetic device to be measured 900. The third sensing assembly 400 and the fourth sensing assembly 500 are relatively close to the first magnetic pole N of the magnetic device to be measured 900. As such, the first sensing assembly 200 and the second sensing assembly 300, along with the third sensing assembly 400 and the fourth sensing assembly 500 can form two sets of outputs with different magnetic field strengths.

The magnetic device to be measured 900 includes a magnetic pole interface extending along a Y direction.

Among the first sensing assembly 200, the second sensing assembly 300, the third sensing assembly 400 and the fourth sensing assembly 500, a sensing signal generated by the sensing elements on one side of the Y direction and the sensing signals generated by the sensing elements on another side of the opposite direction of the Y direction are used to calculate and generate a first output signal.

For example, in an embodiment shown in FIG. 14 and FIG. 15, the first sensing element 211 is the sensing element on one side of the Y direction in the first sensing assembly 200, the fifth sensing element 411 is the sensing element on one side of the Y direction in the third sensing assembly 400; the second sensing element 212 is the sensing element on another side of the opposite direction of the Y direction in the first sensing assembly 200, the sixth sensing element 412 is the sensing element on another side of the opposite direction of the Y direction in the third sensing assembly 400. The above sensing elements are used to calculate and generate a first output signal om21.

For another example, in an embodiment shown in FIG. 16 and FIG. 18, the first sensing element 211 is the sensing element on one side of the Y direction in the first sensing assembly 200, the seventh sensing element 511 is the sensing element on one side of the Y direction in the fourth sensing assembly 500; the fourth sensing element 312 is the sensing element on another side of the opposite direction of the Y direction in the second sensing assembly 300, the sixth sensing element 412 is the sensing element on another side of the opposite direction of the Y direction in the third sensing assembly 400. The above sensing elements are used to calculate and generate another first output signal om41.

Among the first sensing assembly 200, the second sensing assembly 300, the third sensing assembly 400 and the fourth sensing assembly 500, a sensing signal generated by the sensing elements on one side of an X direction and a sensing signal generated by the sensing elements on another side of the opposite direction of the X direction are used to calculate and generate a second output signal.

For example, in an embodiment shown in FIG. 14 and FIG. 15, the fourth sensing element 312 is the sensing element on one side of the X direction in the second sensing assembly 300, the eighth sensing element 512 is the sensing element on one side of the X direction in the fourth sensing assembly 500; the third sensing element 311 is the sensing element on another side of the opposite direction of the X direction in the second sensing assembly 300, the seventh sensing element 511 is the sensing element on another side of the opposite direction of the X direction in the fourth sensing assembly 500. The above sensing elements are used to calculate and generate a second output signal om22.

For another example, in an embodiment shown in FIG. 16 and FIG. 18, the eighth sensing element 512 is the sensing element on one side of the X direction in the fourth sensing assembly 500, the fifth sensing element 411 is the sensing element on one side of the X direction in the third sensing assembly 400; the second sensing element 212 is the sensing element on another side of the opposite direction of the X direction in the first sensing assembly 200, the third sensing element 311 is the sensing element on another side of the opposite direction of the X direction in the second sensing assembly 300. The above sensing elements are used to calculate and generate another second output signal om42.

At least one of the first output signal and the second output signal is used to calculate and generate motion state data of the magnetic device to be measured 900. Specifically, the motion state data includes rotation angle data.

The X direction and the Y direction form the first angle. Preferably, the first angle is 90 degrees.

In an embodiment shown in FIG. 14 and FIG. 15, the first direction D1 is parallel to the Y direction, and the second direction D2 is parallel to the X direction.

In an embodiment shown in FIGS. 16 and 18, the X direction points to a middle direction between the first direction D1 and the second direction D2; an angle between the X direction and the first direction D1 is equal to an angle between the X direction and the second direction D2.

Among the first sensing assembly 200, the second sensing assembly 300, the third sensing assembly 400, and the fourth sensing assembly 500, the sensing elements on one side of the Y direction are used to generate a first sensing signal and a second sensing signal, and the sensing elements on another side of the opposite direction of the Y direction are used to generate a third sensing signal and a fourth sensing signal.

The first sensing signal and the third sensing signal are used to perform a second operation to form a first intermediate signal, and the second sensing signal and the fourth sensing signal are used to perform a second operation to form a second intermediate signal.

For example, in an embodiment shown in FIG. 14 and FIG. 15, the first sensing element 211 is used to generate the first sensing signal, the second sensing element 212 is used to generate the third sensing signal, so the two perform the second operation to form a first intermediate signal op21. In an embodiment, the second operation is a differential operation.

The fifth sensing element 411 is used to generate the second sensing signal, the sixth sensing element 412 is used to generate the fourth sensing signal, so the two perform the second operation to form a second intermediate signal op22. In an embodiment, the second operation is a differential operation.

For another example, in the embodiment shown in FIG. 16 and FIG. 18, the first sensing element 211 is used to generate the first sensing signal, the fourth sensing element 312 is used to generate the third sensing signal, so the two perform the second operation to form another first intermediate signal op41. In an embodiment, the second operation is a differential operation.

The seventh sensing element 511 is used to generate the second sensing signal, the sixth sensing element 412 is used to generate the fourth sensing signal, so the two perform the second operation to form another second intermediate signal op42. In an embodiment, the second operation is a differential operation.

The first intermediate signal and the second intermediate signal are used to perform a second operation to form a first output signal.

For example, in an embodiment shown in FIG. 14 and FIG. 15, the first intermediate signal op21 and the second intermediate signal op22 are used to perform the second operation to form a first output signal om21. In an embodiment, the second operation is a differential operation; when performing the second operation, the difference between the first intermediate signal op21 and the second intermediate signal op22 is taken.

For another example, in an embodiment shown in FIG. 16 and FIG. 18, another first intermediate signal op41 and another second intermediate signal op42 are used to perform the second operation to form another first output signal om41. In an embodiment, the second operation is a differential operation.

As such, the sensing signals of the sensing elements at both ends of the Y direction can be comprehensively considered, and the two sets of sensing signals (i.e., intermediate signals) can be compared and judged, thereby obtaining magnetic field change sensing over a wider range, and this sensing can be completed with only 4 sensing elements.

Among the first sensing assembly 200, the second sensing assembly 300, the third sensing assembly 400, and the fourth sensing assembly 500, the sensing elements on one side of the X direction are used to generate a fifth sensing signal and a sixth sensing signal, and the sensing elements on another side of the opposite direction of the X direction are used to generate a seventh sensing signal and an eighth sensing signal.

The fifth sensing signal and the seventh sensing signal are used to perform a second operation to form a third intermediate signal, and the sixth sensing signal and the eighth sensing signal are used to perform a second operation to form a fourth intermediate signal.

For example, in an embodiment shown in FIG. 14 and FIG. 15, the fourth sensing element 312 is used to generate the fifth sensing signal, the third sensing element 311 is used to generate the seventh sensing signal, so the two perform the second operation to form a third intermediate signal op23. In an embodiment, the second operation is a differential operation.

The eighth sensing element 512 is used to generate the sixth sensing signal, the seventh sensing element 511 is used to generate the eighth sensing signal, so the two perform the second operation to form a fourth intermediate signal op24. In an embodiment, the second operation is a differential operation.

For another example, in the embodiment shown in FIG. 16 and FIG. 18, the eighth sensing element 512 is used to generate the fifth sensing signal, the second sensing element 212 is used to generate the seventh sensing signal, so the two perform the second operation to form another third intermediate signal op43. In an embodiment, the second operation is a differential operation.

The fifth sensing element 411 is used to generate the sixth sensing signal, the third sensing element 311 is used to generate the eighth sensing signal, so the two perform the second operation to form another fourth intermediate signal op44. In an embodiment, the second operation is a differential operation.

The third intermediate signal and the fourth intermediate signal are used to perform a second operation to form a second output signal.

For example, in an embodiment shown in FIG. 14 and FIG. 15, the third intermediate signal op23 and the fourth intermediate signal op24 are used to perform the second operation to form the second output signal om22. In an embodiment, the second operation is a differential operation.

For another example, in an embodiment shown in FIG. 16 and FIG. 18, another third intermediate signal op43 and another fourth intermediate signal op44 are used to perform the second operation to form another second output signal om42. In an embodiment, the second operation is a differential operation.

As such, the sensing signals of the sensing elements at both ends of the X direction can be comprehensively considered, and the two sets of sensing signals (i.e., intermediate signals) can be compared and judged, thereby obtaining magnetic field change sensing over a wider range, and this sensing can be completed with only 4 sensing elements.

For a second embodiment provided in FIG. 14 and FIG. 15, in a first state, the first sensing assembly 200 and the second sensing assembly 300 are relatively far from the first magnetic pole N of the magnetic device to be measured 900; the third sensing assembly 400 and the fourth sensing assembly 500 are relatively close to the first magnetic pole N of the magnetic device to be measured 900.

The magnetic device to be measured 900 includes a magnetic pole interface extending along the first direction D1.

In the second embodiment, in the first state: the first direction D1, Y direction, magnetic pole interface extension direction, spacing direction of the first sensing element 211 and the second sensing element 212, and spacing direction of the fifth sensing element 411 and the sixth sensing element 412 are unified.

Based on this, combined with FIG. 11, the first sensing element 211 is used to generate a first sensing signal, the second sensing element 212 is used to generate a third sensing signal. The fifth sensing element 411 is used to generate a second sensing signal, the sixth sensing element 412 is used to generate a fourth sensing signal.

The fourth sensing element 312 is used to generate a fifth sensing signal, the third sensing element 311 is used to generate a seventh sensing signal. The eighth sensing element 512 is used to generate a sixth sensing signal, the seventh sensing element 511 is used to generate an eighth sensing signal.

Correspondingly, the present application also provides a state detection device, comprising the magnetic sensor 100 in the second embodiment. The state detection device also comprises:

A first intermediate signal operation module 71, coupled to the first sensing element 211 and the second sensing element 212. The first intermediate signal operation module 71 is used to perform a second operation on sensing signals from the first sensing element 211 and the second sensing element 212 to form a first intermediate signal.

A second intermediate signal operation module 72, coupled to the fifth sensing element 411 and the sixth sensing element 412. The second intermediate signal operation module 72 is used to perform a second operation on sensing signals from the fifth sensing element 411 and the sixth sensing element 412 to form a second intermediate signal.

A third intermediate signal operation module 73, coupled to the third sensing element 311 and the fourth sensing element 312. The third intermediate signal operation module 73 is used to perform a second operation on sensing signals from the third sensing element 311 and the fourth sensing element 312 to form a third intermediate signal.

A fourth intermediate signal operation module 74, coupled to the seventh sensing element 511 and the eighth sensing element 512. The fourth intermediate signal operation module 74 is used to perform a second operation on sensing signals from the seventh sensing element 511 and the eighth sensing element 512 to form a fourth intermediate signal.

A first output signal operation module 710, coupled to the first intermediate signal operation module 71 and the second intermediate signal operation module 72. The first output signal operation module 710 is used to perform a second operation on intermediate signals from the first intermediate signal operation module 71 and the second intermediate signal operation module 72 to form a first output signal om11.

A second output signal operation module 720, coupled to the third intermediate signal operation module 73 and the fourth intermediate signal operation module 74. The second output signal operation module 720 is used to perform a second operation on intermediate signals from the third intermediate signal operation module 73 and the fourth intermediate signal operation module 74 to form a second output signal om12.

An output processing module 81, coupled to the first output signal operation module 710 and the second output signal operation module 720. The output processing module 81 is used to calculate and generate motion state data of a magnetic device to be measured, especially to calculate and generate rotation angle data. The output processing module 81 is used to perform operations on the first output signal om11 and the second output signal om12 from the first output signal operation module 710 and the second output signal operation module 720 to generate at least rotation angle data.

A storage module 82, coupled to the output processing module 81. The storage module 82 is used to store at least correction information for the rotation angle data.

In an embodiment, the state detection device also includes an output unit 83 coupled to the output processing module 81, used to produce a final device output.

Moreover, if the second operation is a differential operation, then the differential outputs of sensing elements in a same sensing assembly can cause the magnetic field components perpendicular to a substrate plane (for example, an XY plane) to be cancelled, so the sensing assembly only generates output for the magnetic field components parallel to the substrate plane.

Furthermore, since the second operation (in an example, differential operation) is applied to the intermediate signals, the magnetic sensor has a superior resistance effect against interference magnetic fields.

For a fourth embodiment provided in FIG. 16 and FIG. 18, in a first state, the first sensing assembly 200 and the second sensing assembly 300 are relatively far from a first magnetic pole N of the magnetic device to be measured 900; the third sensing assembly 400 and the fourth sensing assembly 500 are relatively close to the first magnetic pole N of the magnetic device to be measured 900.

The magnetic device to be measured 900 includes a magnetic pole interface extending along a Y direction.

The Y direction points to a middle direction of the first direction D1 and the opposite direction of the second direction D2. An X direction points to a middle direction of the first direction D1 and the second direction D2.

In the fourth embodiment, in the first state: the Y direction and the magnetic pole interface extension direction are unified, the first direction D1, the spacing direction of the first sensing element 211 and the second sensing element 212, and the spacing direction of the fifth sensing element 411 and the sixth sensing element 412 are unified; and the aforementioned two directions are set at a second angle. Preferably, the second angle is half of the first angle. Preferably, the first angle is 90 degrees and the second angle is 45 degrees.

Based on this, combined with FIG. 17, the first sensing element 211 is used to generate a first sensing signal, the fourth sensing element 312 is used to generate a third sensing signal. The seventh sensing element 511 is used to generate a second sensing signal, the sixth sensing element 412 is used to generate a fourth sensing signal.

The eighth sensing element 512 is used to generate a fifth sensing signal, the second sensing element 212 is used to generate a seventh sensing signal. The fifth sensing element 411 is used to generate a sixth sensing signal, the third sensing element 311 is used to generate an eighth sensing signal.

Correspondingly, the present application also provides a state detection device, comprising the magnetic sensor 100 in the fourth embodiment. The state detection device also comprises:

A first intermediate signal operation module 71, coupled to the first sensing element 211 and the fourth sensing element 312. The first intermediate signal operation module 71 is used to perform a second operation on sensing signals from the first sensing element 211 and the fourth sensing element 312 to form a first intermediate signal.

A second intermediate signal operation module 72, coupled to the seventh sensing element 511 and the sixth sensing element 412. The second intermediate signal operation module 72 is used to perform a second operation on sensing signals from the seventh sensing element 511 and the sixth sensing element 412 to form a second intermediate signal.

A third intermediate signal operation module 73, coupled to the second sensing element 212 and the eighth sensing element 512. The third intermediate signal operation module 73 is used to perform a second operation on sensing signals from the second sensing element 212 and the eighth sensing element 512 to form a third intermediate signal.

A fourth intermediate signal operation module 74, coupled to the third sensing element 311 and the fifth sensing element 411. The fourth intermediate signal operation module 74 is used to perform a second operation on sensing signals from the third sensing element 311 and the fifth sensing element 411 to form a fourth intermediate signal.

A first output signal operation module 710, coupled to the first intermediate signal operation module 71 and the second intermediate signal operation module 72. The first output signal operation module 710 is used to perform a second operation on intermediate signals from the first intermediate signal operation module 71 and the second intermediate signal operation module 72 to form a first output signal om41.

A second output signal operation module 720, coupled to the third intermediate signal operation module 73 and the fourth intermediate signal operation module 74. The second output signal operation module 720 is used to perform a second operation on intermediate signals from the third intermediate signal operation module 73 and the fourth intermediate signal operation module 74 to form a second output signal om42.

An output processing module 81, coupled to the first output signal operation module 710 and the second output signal operation module 720. The output processing module 81 is used to calculate and generate motion state data of a magnetic device to be measured, especially to calculate and generate rotation angle data. The output processing module 81 is used to perform operations on the first output signal om41 and the second output signal om42 from the first output signal operation module 710 and the second output signal operation module 720 to generate at least rotation angle data.

A storage module 82, coupled to the output processing module 81. The storage module 82 is used to store at least correction information for the rotation angle data.

In an embodiment, the state detection device also includes an output unit 83 coupled to the output processing module 81, used to produce a final device output.

In summary, the magnetic sensor and state detection device provided by the present application, by setting sensing assemblies at four positions with center-symmetry on the substrate, and configuring the sensing assemblies so that two of them have sensing elements arranged along a first direction and the other two along a second direction, can obtain sensitivity in at least two directions, and signals obtained by the two sensing assemblies can complement each other to obtain magnetic field information in the entire area. Based on the layout and internal structure configuration of the sensing assemblies, it can greatly reduce the demand for the number of sensing elements, achieve lower costs and energy consumption, and save circuit area. Even if magnetic field interference occurs in a direction, the two sensing assemblies present changes in a same direction externally and can resist such interference so that it is not reflected in the output of the magnetic sensor, thereby improving the credibility and accuracy of the outputs.

It should be understood that although the detailed description is given according to embodiments, it does not mean that each embodiment only contains one independent technical solution. The description method of the detailed description is only for clarity. Those skilled in the art should regard the detailed description as a whole, and the technical solutions in each embodiment can also be appropriately combined to form other embodiments understandable to those skilled in the art.

The series of detailed descriptions listed above are only specific descriptions of feasible embodiments of the present application and are not intended to limit the scope of protection of the present application. Any equivalent embodiments or changes made without departing from the spirit of the present application should be included within the scope of protection of the present application.

1. A magnetic sensor, comprising:
a substrate, including a carrying surface;
a first sensing assembly, provided at a first position on the carrying surface, comprising a first sensing element and a second sensing element spaced apart along a first direction;
a second sensing assembly, provided at a second position on the carrying surface, comprising a third sensing element and a fourth sensing element spaced apart along a second direction;
a third sensing assembly, provided at a third position on the carrying surface, comprising a fifth sensing element and a sixth sensing element spaced apart along the first direction;
a fourth sensing assembly, provided at a fourth position on the carrying surface, comprising a seventh sensing element and an eighth sensing element spaced apart along the second direction;
wherein a convex polygon formed by connecting the first position, the second position, the third position and the fourth position is center-symmetrical with respect to a geometric center of the carrying surface; the first direction and the second direction form a first angle.

2. The magnetic sensor according to claim 1, wherein the number of sensing elements in the first sensing assembly is 2; the number of sensing elements in the second sensing assembly is 2; the number of sensing elements in the third sensing assembly is 2; the number of sensing elements in the fourth sensing assembly is 2.

3. The magnetic sensor according to claim 1, wherein the first angle is 90 degrees; the convex polygon is a square.

4. The magnetic sensor according to claim 1, wherein the first sensing assembly comprises a first magnetic flux concentrator, the first sensing element and the second sensing element are provided on an extension surface of the first magnetic flux concentrator; the first direction and the second direction are parallel to the extension surface of the first magnetic flux concentrator; sensing directions of the first sensing element and the second sensing element are perpendicular to the extension surface of the first magnetic flux concentrator.

5. The magnetic sensor according to claim 4, wherein the first sensing element and the second sensing element are provided between the first magnetic flux concentrator and the substrate.

6. The magnetic sensor according to claim 4, wherein the first sensing element and the second sensing element are symmetrical with respect to a symmetry axis passing through a geometric center of the first magnetic flux concentrator and extending along the second direction; projections of the first sensing element and the second sensing element on the first magnetic flux concentrator at least partially overlap with the extension surface of the first magnetic flux concentrator;
the second sensing assembly comprises a second magnetic flux concentrator; the third sensing element and the fourth sensing element are symmetrical with respect to a symmetry axis passing through a geometric center of the second magnetic flux concentrator and extending along the first direction; projections of the third sensing element and the fourth sensing element on the second magnetic flux concentrator at least partially overlap with the extension surface of the second magnetic flux concentrator;
the third sensing assembly comprises a third magnetic flux concentrator; the fifth sensing element and the sixth sensing element are symmetrical with respect to a symmetry axis passing through a geometric center of the third magnetic flux concentrator and extending along the second direction; projections of the fifth sensing element and the sixth sensing element on the third magnetic flux concentrator at least partially overlap with the extension surface of the third magnetic flux concentrator;
the fourth sensing assembly comprises a fourth magnetic flux concentrator; the seventh sensing element and the eighth sensing element are symmetrical with respect to a symmetry axis passing through a geometric center of the fourth magnetic flux concentrator and extending along the first direction; projections of the seventh sensing element and the eighth sensing element on the fourth magnetic flux concentrator at least partially overlap with the extension surface of the fourth magnetic flux concentrator.

7. The magnetic sensor according to claim 1, wherein when the magnetic sensor is close to a magnetic device to be measured, at least in a first state, at least one of the first sensing assembly, the second sensing assembly, the third sensing assembly and the fourth sensing assembly is close to a first magnetic pole of the magnetic device to be measured, and at least another one of the first sensing assembly, the second sensing assembly, the third sensing assembly and the fourth sensing assembly is relatively far from the first magnetic pole.

8. The magnetic sensor according to claim 1, wherein among the first sensing assembly, the second sensing assembly, the third sensing assembly and the fourth sensing assembly, a sensing signal generated by the sensing elements on one side of a Y direction and a sensing signal generated by the sensing elements on another side of the opposite direction of the Y direction are used to calculate and generate a first output signal;
among the first sensing assembly, the second sensing assembly, the third sensing assembly and the fourth sensing assembly, a sensing signal generated by the sensing elements on one side of an X direction and a sensing signal generated by the sensing elements on another side of the opposite direction of the X direction are used to calculate and generate a second output signal; wherein the X direction and the Y direction form the first angle;
at least one of the first output signal and the second output signal is used to calculate and generate motion state data of a magnetic device to be measured; the motion state data includes rotation angle data.

9. The magnetic sensor according to claim 1, wherein the magnetic sensor is provided on one side of a magnetic device to be measured in a third direction, and a geometric center of the substrate is aligned with a geometric center of the magnetic device to be measured; wherein the third direction is perpendicular to both the first direction and the second direction.

10. The magnetic sensor according to claim 9, wherein in a first state, the first sensing assembly and the second sensing assembly are symmetrically arranged with respect to the third sensing assembly and the fourth sensing assembly relative to a magnetic pole interface extending along a Y direction;
among the first sensing assembly, the second sensing assembly, the third sensing assembly and the fourth sensing assembly, the sensing elements on one side of the Y direction are used to generate a first sensing signal and a second sensing signal, and the sensing elements on another side of the opposite direction of the Y direction are used to generate a third sensing signal and a fourth sensing signal; the first sensing signal and the third sensing signal are used to perform a first operation to form a first intermediate signal, and the second sensing signal and the fourth sensing signal are used to perform a first operation to form a second intermediate signal; the first intermediate signal and the second intermediate signal are used to perform a second operation to form a first output signal;
among the first sensing assembly, the second sensing assembly, the third sensing assembly and the fourth sensing assembly, the sensing elements on one side of an X direction are used to generate a fifth sensing signal and a sixth sensing signal, and the sensing elements on another side of the opposite direction of the X direction are used to generate a seventh sensing signal and an eighth sensing signal; the fifth sensing signal and the seventh sensing signal are used to perform a first operation to form a third intermediate signal, and the sixth sensing signal and the eighth sensing signal are used to perform a first operation to form a fourth intermediate signal; the third intermediate signal and the fourth intermediate signal are used to perform a second operation to form a second output signal;
wherein the first operation is a superposition operation, and the second operation is a differential operation; the X direction and the Y direction form the first angle.

11. The magnetic sensor according to claim 9, wherein in a first state, the first sensing assembly and the second sensing assembly are symmetrically arranged with respect to the third sensing assembly and the fourth sensing assembly relative to a magnetic pole interface extending along the first direction;
the first sensing element (211) is used to generate a first sensing signal, the second sensing element (212) is used to generate a third sensing signal; the fifth sensing element (411) is used to generate a second sensing signal, the sixth sensing element (412) is used to generate a fourth sensing signal;
the fourth sensing element (312) is used to generate a fifth sensing signal, the third sensing element (311) is used to generate a seventh sensing signal; the eighth sensing element (512) is used to generate a sixth sensing signal, the seventh sensing element (511) is used to generate an eighth sensing signal.

12. The magnetic sensor according to claim 9, wherein in a first state, the first sensing assembly and the second sensing assembly are symmetrically arranged with respect to the third sensing assembly and the fourth sensing assembly relative to a magnetic pole interface extending along a Y direction; the Y direction points to a middle direction of the first direction and the opposite direction of the second direction;
the first sensing element (211) is used to generate a first sensing signal, the fourth sensing element (312) is used to generate a third sensing signal; the seventh sensing element (511) is used to generate a second sensing signal, the sixth sensing element (412) is used to generate a fourth sensing signal;
the eighth sensing element (512) is used to generate a fifth sensing signal, the second sensing element (212) is used to generate a seventh sensing signal; the fifth sensing element (411) is used to generate a sixth sensing signal, the third sensing element (311) is used to generate an eighth sensing signal.

13. The magnetic sensor according to claim 1, wherein the magnetic sensor is provided on one side of a magnetic device to be measured in a width direction, and the magnetic sensor is flush with the magnetic device to be measured in a third direction; wherein the third direction is perpendicular to both the first direction and the second direction.

14. The magnetic sensor according to claim 13, wherein in a first state, the first sensing assembly and the second sensing assembly are relatively far from a first magnetic pole of the magnetic device to be measured, and the third sensing assembly and the fourth sensing assembly are relatively close to the first magnetic pole of the magnetic device to be measured; the magnetic device to be measured includes a magnetic pole interface extending along a Y direction;
among the first sensing assembly, the second sensing assembly, the third sensing assembly and the fourth sensing assembly, the sensing elements on one side of the Y direction are used to generate a first sensing signal and a second sensing signal, and the sensing elements on another side of the opposite direction of the Y direction are used to generate a third sensing signal and a fourth sensing signal; the first sensing signal and the third sensing signal are used to perform a second operation to form a first intermediate signal, and the second sensing signal and the fourth sensing signal are used to perform a second operation to form a second intermediate signal; the first intermediate signal and the second intermediate signal are used to perform a second operation to form a first output signal;
among the first sensing assembly, the second sensing assembly, the third sensing assembly and the fourth sensing assembly, the sensing elements on one side of an X direction are used to generate a fifth sensing signal and a sixth sensing signal, and the sensing elements on another side of the opposite direction of the X direction are used to generate a seventh sensing signal and an eighth sensing signal; the fifth sensing signal and the seventh sensing signal are used to perform a second operation to form a third intermediate signal, and the sixth sensing signal and the eighth sensing signal are used to perform a second operation to form a fourth intermediate signal; the third intermediate signal and the fourth intermediate signal are used to perform a second operation to form a second output signal;
wherein the second operation is a differential operation; wherein the X direction and the Y direction form the first angle.

15. The magnetic sensor according to claim 13, wherein in a first state, the first sensing assembly and the second sensing assembly are relatively far from a first magnetic pole of the magnetic device to be measured, and the third sensing assembly and the fourth sensing assembly are relatively close to the first magnetic pole of the magnetic device to be measured; the magnetic device to be measured includes a magnetic pole interface extending along the first direction;
the first sensing element (211) is used to generate a first sensing signal, the second sensing element (212) is used to generate a third sensing signal; the fifth sensing element (411) is used to generate a second sensing signal, the sixth sensing element (412) is used to generate a fourth sensing signal;
the fourth sensing element (312) is used to generate a fifth sensing signal, the third sensing element (311) is used to generate a seventh sensing signal; the eighth sensing element (512) is used to generate a sixth sensing signal, the seventh sensing element (511) is used to generate an eighth sensing signal.

16. The magnetic sensor according to claim 13, wherein in a first state, the first sensing assembly and the second sensing assembly are relatively far from a first magnetic pole of the magnetic device to be measured, and the third sensing assembly and the fourth sensing assembly are relatively close to the first magnetic pole of the magnetic device to be measured; the magnetic device to be measured includes a magnetic pole interface extending along a Y direction; the Y direction points to a middle direction of the first direction and the opposite direction of the second direction;
the first sensing element (211) is used to generate a first sensing signal, the fourth sensing element (312) is used to generate a third sensing signal; the seventh sensing element (511) is used to generate a second sensing signal, the sixth sensing element (412) is used to generate a fourth sensing signal;
the eighth sensing element (512) is used to generate a fifth sensing signal, the second sensing element (212) is used to generate a seventh sensing signal; the fifth sensing element (411) is used to generate a sixth sensing signal, the third sensing element (311) is used to generate an eighth sensing signal.

17. The magnetic sensor according to claim 1, wherein the first sensing element includes at least one Hall unit; the charge deflection electrode at the Hall unit is used to form a first Hall output, and the charge repulsion electrode at the Hall unit is used to form a second Hall output; the first sensing assembly uses the first Hall output and the second Hall output as a signal output of the first sensing element.

18. The magnetic sensor according to claim 17, wherein the first sensing element comprises two Hall units or four Hall units; the charge deflection electrodes of the Hall units are coupled, the charge repulsion electrodes of the Hall units are coupled, power supply electrodes of the Hall units are coupled, and reference electrodes of the Hall units are coupled;
the first sensing element, the second sensing element, the third sensing element, the fourth sensing element, the fifth sensing element, the sixth sensing element, the seventh sensing element and the eighth sensing element are configured to have a same structure.

19. A state detection device, comprising the magnetic sensor according to claim 1; and,
a first intermediate signal operation module coupled to the first sensing element and the second sensing element, a second intermediate signal operation module coupled to the fifth sensing element and the sixth sensing element, a third intermediate signal operation module coupled to the third sensing element and the fourth sensing element, a fourth intermediate signal operation module coupled to the seventh sensing element and the eighth sensing element; and, a first output signal operation module coupled to the first intermediate signal operation module and the second intermediate signal operation module, a second output signal operation module coupled to the third intermediate signal operation module and the fourth intermediate signal operation module; and, an output processing module coupled to the first output signal operation module and the second output signal operation module; and, a storage module coupled to the output processing module; or,
a first intermediate signal operation module coupled to the first sensing element and the fourth sensing element, a second intermediate signal operation module coupled to the seventh sensing element and the sixth sensing element, a third intermediate signal operation module coupled to the second sensing element and the eighth sensing element, a fourth intermediate signal operation module coupled to the third sensing element and the fifth sensing element; and, a first output signal operation module coupled to the first intermediate signal operation module and the second intermediate signal operation module, a second output signal operation module coupled to the third intermediate signal operation module and the fourth intermediate signal operation module; and, an output processing module coupled to the first output signal operation module and the second output signal operation module; and, a storage module coupled to the output processing module;
wherein the first output signal operation module and the second output signal operation module are used to perform a second operation, the output processing module is used to calculate and generate rotation angle data, and the storage module is used to store at least correction information for the rotation angle data.
